(19) United States
(12) Patent Application Publication
(10) Pub. No.: US 2015/0028876 A1
(43) Pub. Date: Jan. 29, 2015

(54) METHOD AND APPARATUS FOR TESTING A LIGHTING DEVICE UNDER TEMPERATURE

(71) Applicants: Nathan McLaughlin, Portland, OR (US); Benjamin Smith, Portland, OR (US); Norbert Puetz, Ottawa (CA)

(72) Inventors: Nathan McLaughlin, Portland, OR (US); Benjamin Smith, Portland, OR (US); Norbert Puetz, Ottawa (CA)

(21) Appl. No.: 14/340,440

(22) Filed: Jul. 24, 2014

Related U.S. Application Data
(60) Provisional application No. 61/857,825, filed on Jul. 24, 2013.

(51) Int. Cl. G01R 31/44; G01N 21/21; G01N 21/25

(52) U.S. Cl. CPC G01R 31/44; G01N 21/255; G01N 21/21; G01N 2201/125
USPC 324/414

(57) ABSTRACT

An apparatus to measure and collect data relating to properties of light for a plurality of light-producing devices comprises a rail having a longitudinal axis along which the plurality of light-producing devices is aligned. A measurement tool is mounted on the rail and moved under motor control to measure the data for each of the plurality of light-producing devices.

### CROSS-REFERENCE TO RELATED APPLICATIONS

This application claims the benefit of U.S. Provisional Application No. 61/857,825, filed Jul. 24, 2013, the entire contents of which are hereby incorporated by reference herein.

### TECHNICAL FIELD

Embodiments of the present invention are in the field of measuring or testing a lighting device, such as a light emitting diode, across a range of temperatures.

### BACKGROUND

Quantum dots having a high photoluminescence quantum yield (PLQY) may be applicable as down-converting materials in down-converting composites used in solid-state lighting device applications. Down-converting materials are used to improve the performance, efficiency and color choice in lighting applications, particularly light emitting diodes (LEDs). In such applications, quantum dots absorb light of a particular first (available or selected) wavelength, usually blue, and then emit light at a second wavelength, usually red or green. The performance and efficiency of the LEDs may vary as they age and/or while at different operating temperatures.

Light sources, or light-producing devices, such as LEDs, in particular, LEDs packaged with quantum dot down-converting composites or films, may be tested or measured, for example, during or after manufacture, to collect data about the operation of the LEDs, such as colorimetric data, as a function of temperature and/or time. What is needed is a tool for collecting such data that would help in optimizing the light sources, or one or more components of the light sources, for example, the quantum dot down converters. What is also needed is a tool that allows testing to occur and measurements to be made without removing the light sources from their test location, thereby eliminating the need for a user to perform such measurements.

### BRIEF DESCRIPTION OF THE DRAWINGS

Embodiments of the present invention are illustrated by way of example, and not limitation, in the figures of the accompanying drawings in which:

FIG. 1 illustrates an embodiment of the invention.

### DETAILED DESCRIPTION

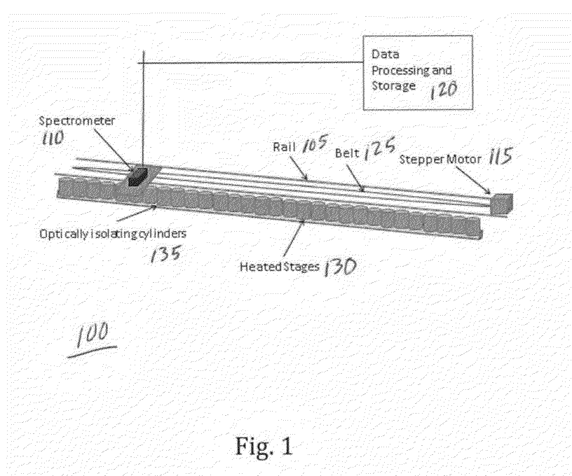

One or more embodiments described herein are directed to testing lighting devices, or light-producing devices, such as LEDs, including LEDs that use down-converting materials such as quantum dots and/or phosphors to improve the performance, efficiency and color choice in lighting applications. In one embodiment, with reference to FIG. 1, an apparatus 100 measures and collects data relating to properties of light for an array or line up of light-producing devices, for example, in a manufacturing or testing environment. Light-producing devices, in one embodiment, include one or more light-emitting diode (LED) devices, wherein the devices may include a quantum-dot and/or phosphor down converter composite layers. Embodiments contemplate being able to measure any property of light for a light-producing device, given an appropriate tool with which to measure the property. For example, apparatus 100 is capable of measuring such properties of light as: intensity, polarization state, spectral power distribution, colorimetric data, color temperature, color rendering index (CRI), correlated color temperature (CCT), and luminous efficacy of radiation (LER).

In one embodiment, apparatus 100 includes a rail 105. The rail has a longitudinal axis along which a number of light-producing devices (not shown) are aligned. A measurement or testing tool 110 is mounted to or on the rail in such a way as to be able to roll or slide or otherwise move along the rail. The tool is used to measure the data relating to properties of light for each of the light-producing devices. In FIG. 1, the measurement tool is a spectrometer 110, but it is appreciated by those skilled in the art that any tool that could be used to measure and/or test some property of light, such as those properties noted above, produced by the devices, including, but not limited to, a spectrophotometer, a spectrograph, a spectroscope, a spectroradiometer, a spectrocolorimeter, and a color temperature meter.

In one embodiment, a motion control positioning system, such as a motor 115, is coupled to the tool 110 to move the tool along the rail to the locations of the light-producing devices, wherein the motion control positioning system holds the tool at each of the locations at least for sufficient time to measure the data for each of the light-producing devices. A data processing system 120 is coupled to the tool, and in one embodiment, a software program including machine instructions to be executed by the system 120 collects the data for each of the light-producing devices from the measuring tool. Data storage, in the form of volatile and/or non-volatile (permanent) memory or storage, in the system 120 is used to store the collected data. The stored collected data can then be accessed at a later time, for example, to analyze the performance, quality, or other characteristics of the light-producing devices, including any changes in such characteristics, as the devices operate over an extending period of time, and subjected to a varying range of temperatures.

According to one embodiment, the motor is coupled to the tool to repeatedly move the tool along the rail to a respective location, as the tool measures the data, for each of light-producing devices, such that the apparatus repeatedly measures the data for each of the light-producing devices at a selected frequency and over a selected period of time.

The motor 115, in one embodiment, is a computer-controlled stepper motor and includes an associated driver circuit to move and hold the tool along the rail at the respective location so that the tool 110 can measure the data for each of the light-producing devices. A stepper motor is an electric motor that divides a full rotation into a number of equal steps. The motor's position can then be commanded to move and hold at one of these steps. The motor is appropriately sized to a particular application, for example, in an embodiment, the stepper motor's position may be commanded to move and hold at a step so that the tool to which it is coupled moves and holds at an appropriate location, for a determined period of time, near or over a light-producing device, during which the tool takes appropriate measurements of one or more properties of light emitted by the light-producing device. According to one embodiment, the stepper motor is controlled by a dedicated or stand-alone microcontroller. In another embodiment, the stepper motor is controlled by machine instructions executed by processor 120. The machine instructions may be stored in and accessed from associated data storage.

In one embodiment, a pulley (not shown) is coupled to the tool 110, and another pulley is coupled to the stepper motor. A belt 125 is wrapped around the pulleys so that as the stepper motor moves, the tool moves along the rail, and as the stepper motor holds, the tool's location holds at the location of one of the light-producing devices. While the embodiment of the motion control positioning system described herein uses a stepper motor, it is appreciated that other types of motion control or automation systems may be used in which the position or velocity of the measuring tool is controlled using some type of device such as a hydraulic pump, linear actuator, electric motor, a servo, etc.

According to embodiments, the apparatus 100 further comprises a heating element 130 to direct a quantity of heat energy (i.e., provide a particular amount of heat) to each of the light-producing devices arrayed along the rail 105. The heating element may include multiple stages, wherein each stage is to direct a same or different quantity of heat energy to a respective one of light-producing devices to achieve a testing temperature at which to operate the light-producing device. In one embodiment, the different stages are independently controlled both in terms of temperature at, and the duration of time under, which the stages are delivering heat to a light-producing device.

In one embodiment, the quantity of heat energy is directed to the respective one of the light-producing devices at least when the tool 110 is collecting data relating to the one light-producing device. In one embodiment, the quantity of heat energy is directed to a particular light-producing device for a sufficient time to simulate or otherwise test the performance and/or efficiency of the device as it ages. For example, heat may be applied to the device at temperatures exceeding the normal operating range of temperatures for the device to simulate/accelerate aging of the device and measure operation of the device under such conditions.

The tool 110 may be susceptible to errant or incorrect measurements if stray light is received from a device other than the light-producing device under test or measurement. Thus, in one embodiment, a protective structure 135 is provided such that, as the tool measures the data for a particular light-producing device, the tool is to receive substantially only light from that one light-producing device. According to the embodiment illustrated in FIG. 1, the protective structure is a cylinder that surrounds the light-producing device. FIG. 1 illustrates an array of such cylinders, each housing a light-producing device, with an opening at the top of each cylinder through which the tool measures light emanating from the light-producing device. In one embodiment, the inside surface of the cylinder walls are lined with diffusely reflective material. For example, the inside surface walls are lined with microcellular (or “microfoamed”) polyethylene terephthalate (MCPET) material.

Thus, an apparatus capable of measuring lighting devices such as LEDs, as they are being heated, is described. Many uses are possible for the tool. For example, colorimetric data may be collected as a function of time and/or temperature. Embodiments of the invention contemplate a tool which measures any type of operating light producing devices (for example light emitting diodes, and for example light emitting diodes containing quantum dot down converters), one at a time, and repeatedly, as the devices age and are subjected to varied temperatures. A measuring tool such as a spectrometer is mounted to a long rail and moved along the rail, for example, using a belt and one or more stepper motors. The position proximate, e.g., directly above, each sample (device) is recorded and the spectrometer stops at each device and takes a measurement. This process may be repeated at the desired frequency, as controlled, for example, by a software program executing on processor 120. To prevent light from the neighboring devices from entering or otherwise affecting the measuring tool (spectrometer) during each measurement, the devices are separated from each other, for example, by cylinders. By or beneath each device is a heater, e.g., a DC powered heater, which can be set to achieve the desired test temperature of the devices, for a desired test time for the devices. Such embodiments allow the collection of spectral data of the devices at operating temperature, which can then be used to optimize the design of the devices, or various components of the devices, such as the down converters.

Data processing and storage 120 controls automated performance of one or more operations of the methods described herein, in accordance with embodiments of the invention. An exemplary such system includes a processor, a main memory (e.g., read-only memory (ROM), flash memory, dynamic random access memory (DRAM) such as synchronous DRAM (SDRAM), a static memory (e.g., flash memory, static random access memory (SRAM), etc.), and a secondary memory (e.g., a data storage device), which communicate with each other via a bus. The processor represents one or more general-purpose processing devices such as a microprocessor, central processing unit, or the like. More particularly, the processor may be a complex instruction set computing (CISC) microprocessor, reduced instruction set computing (RISC) microprocessor, very long instruction word (VLIW) microprocessor, etc. The processor may also be one or more special-purpose processing devices such as an application specific integrated circuit (ASIC), a field programmable gate array (FPGA), a digital signal processor (DSP), network processor, or the like. The processor can be configured to execute processing logic for performing the operations and steps discussed herein, according to an embodiment.

System 120 may further include a network interface device, a video display unit, an input device (e.g., a keyboard), a cursor control device (e.g., a mouse), and a signal generation device (e.g., a speaker). Secondary memory may also be included such as a machine-accessible storage medium (or more specifically a computer-readable storage medium) on which is stored one or more sets of instructions (e.g., a software program) embodying any one or more of the methodologies or functions described herein. The software may also reside, completely or at least partially, within the main memory and/or within the processor during execution thereof by the system, the main memory and the processor also constituting machine-readable storage media. The software may further be transmitted or received over a network via the network interface device.

While the machine-accessible storage medium in an exemplary embodiment may be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of embodiments of the invention. The term “machine-readable storage medium” shall accordingly be taken to include, but not be limited to, solid-state memories, and optical and magnetic media, and other non-transitory machine-readable storage medium.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. An apparatus to measure and collect data relating to properties of light for a plurality of light-producing devices, comprising:
a rail having a longitudinal axis along which the plurality of light-producing devices is aligned;
a measurement tool mounted on the rail to measure the data for each of the plurality of light-producing devices;
a motion control positioning system coupled to the tool to move the tool along the rail to a respective location, as the tool measures the data, for each of the plurality of light-producing devices;
a processor coupled to the tool;
a software program including machine instructions to be executed by the processor to collect the data for each of the plurality of light-producing devices; and
memory coupled to the processor in which to store the collected data.

2. The apparatus of claim 1, wherein at least one of the plurality of light-producing devices comprises a light-emitting diode (LED).

3. The apparatus of claim 2, wherein the at least one of the plurality of light-producing devices further comprises a plurality of quantum-dot down converters.

4. The apparatus of claim 1, wherein the measurement tool is selected from a group of measurement tools consisting of: a spectrometer, a spectrophotometer, a spectrograph, a spectroscope, a spectroradiometer, a spectrocolorimeter, and a color temperature meter.

5. The apparatus of claim 4, wherein the properties of light comprise one or more of intensity, polarization state, spectral power distribution, colorimetric data, color temperature, color rendering index (CRI), correlated color temperature (CCT), and luminous efficacy of radiation (LER).

6. The apparatus of claim 1, wherein the motion control positioning system comprises a motor and wherein the motor is coupled to the tool to move the tool along the rail to a respective location, as the tool measures the data, for each of the plurality of light-producing devices.

7. The apparatus of claim 6, wherein the motor comprises a stepper motor and associated driver circuit to move and hold the tool along the rail at the respective location so that the tool can measure the data for each of the plurality of light-producing devices.

8. The apparatus of claim 7, wherein a pulley is coupled to the tool, and a belt is coupled to the pulley and the stepper motor, wherein the stepper motor drives the belt to move the tool along the rail to a respective location for each of the plurality of light-producing devices.

9. The apparatus of claim 1, further comprising a heating element to direct a quantity of heat energy to each of the plurality of light-producing devices.

10. The apparatus of claim 9, wherein the heating element comprises stages, wherein each stage is to direct a quantity of heat energy to a respective one of the plurality of light-producing devices to achieve a testing temperature in which to operate the light-producing device.

11. The apparatus of claim 1, further comprising a protective structure such that, as the tool measures the data, the tool is to receive substantially only light from one of the plurality of light-producing devices at a time as the motor coupled to the tool moves the tool along the rail to a respective location for each of the plurality of light-producing devices.

12. The apparatus of claim 1, wherein the motor coupled to the tool to move the tool along the rail to a respective location, as the tool measures the data, for each of the plurality of light-producing devices, repeatedly moves the tool along the rail to the respective location for each of the plurality of light-producing devices such that the apparatus repeatedly measures the data for each of the plurality of light-producing devices at a selected frequency and over a selected period of time.

13. The apparatus of claim 12, wherein the software program further comprises machine instructions to cause the motor coupled to the tool to move the tool along the rail to a respective location, as the tool measures the data, for each of the plurality of light-producing devices.
